(19) United States
(12) Patent Application Publication
(10) Pub. No.: US 2015/0020869 A1
(43) Pub. Date: Jan. 22, 2015

(54) APPLICATION OF FLUORINE DOPED TIN (IV) OXIDE SNO2:F FOR MAKING A HEATING LAYER ON A PHOTOVOLTAIC PANEL, AND THE PHOTOVOLTAIC PANEL

(71) Applicant: ML SYSTEM Spólka z ograniczona odpowiedzialnoscia, Rzeszów (PL) (PL)

(72) Inventors: Krzysztof Skupien, Krakow (PL); Pawel Boratynski, Krakow (PL); Edyta Stanek, Rzeszow (PL); Dawid Cycon, Rzeszow (PL)

(73) Assignee: ML SYSTEM Spólka z ograniczona odpowiedzialnoscia, Rzeszow (PL) (PL)

(21) Appl. No.: 14/373,061

(22) PCT Filed: Feb. 14, 2013
(86) PCT No.: PCT/PL2013/000017

§ 371 Date: Jul. 18, 2014

(30) Foreign Application Priority Data
Feb. 16, 2012 (EP) 1246008.7

(51) Int. Cl. H01L 31/042; H01L 31/0216

(52) U.S. Cl. CPC H02S 40/00; H01L 31/02167; H01L 31/0424
USPC 136/251; 136/244

(57) ABSTRACT

The invention consists in application of fluorine doped tin (IV) oxide SnO₂:F for making a heating layer on a photovoltaic panel. The invention consists also in a photovoltaic panel characterized in that its front part is covered with a conductive layer of fluorine doped tin (IV) oxide SnO₂:F, with the electrodes deposited thereon. The conductive layer becomes a heating layer when conducted to the source of electric current. In a preferred embodiment a transparent polymer film is applied thereon, inseparably and permanently bound with the conductive layer of fluorine doped tin (IV) oxide SnO₂:F and the photovoltaic cell.

The subject of the invention consists in application of fluorine doped tin (IV) oxide SnO₂:F (FTO) for making a heating layer on a photovoltaic panel, and the electromagnetic radiation (preferably solar energy) into electric energy.

Application of fluorine doped tin (IV) oxide SnO₂:F in defrosting of the car windows is known from the state of the art.

Besides, the photovoltaic panels with laminar structure are known. The photovoltaic cells, converting solar energy into electric energy, are their most important part. Single cell is a semiconductor with p-n junction in its structure. The photovoltaic panels are manufactured with use of various types of semiconducting materials. According to their type panels are classified as silicon of monocrystalline type (c-Si), silicon of polycrystalline type (m-Si) and panels made in thin-layers technologies of amorphous silicon (a-Si, a-Si:H), Copper Indium Selenide (CIS) or Copper Indium Gallium Selenide (CIGS) and cadmium telluride (CdTe). Front part of the photovoltaic panels is made from glass protecting the photovoltaic cells, while the whole structure is closed in a frame which is a constructional element enabling fastening of the panel to the supporting structure.

All known photovoltaic panels, if not installed on vertical facades, are susceptible to be covered with a layer of frost or snow during precipitation at temperatures close to or below zero degrees Celsius. This results in significant loss of performance in conditions where a part of the panel surface is obscured e.g. by snow, frost, etc., and the overall efficiency of whole photovoltaic installation decreases. This problem occurs in winter, at snowy weather and temperatures below zero degrees Celsius. Known snow removal and de-icing systems of photovoltaic panels provide heating by electric heating mats made of resistance wire mounted below the panel or systems with liquid medium (a piping system mounted under the panel). By their nature, the heating mats cannot be placed directly in a place demanding de-icing or defrosting, i.e., on the front part, but they are placed under the panel. This causes undesirable heat loss on its way from the mat towards the front part of the panel.

A solar cell for the supply of electric power is also known from Japanese patent No. JP2002021265. The solar cell is provided with a heating element for melting snow. However, the heating element is provided only on a part of solar cell, what hinders uniform heating of a whole surface of solar cell.

The invention consists in application of fluorine doped tin (IV) oxide SnO₂:F (FTO) for receiving a heating layer on a photovoltaic panel.

The invention consists also in a photovoltaic panel comprising a front part and a frame with photovoltaic cell or cells placed within, characterized in that is front part is covered with a conductive layer of fluorine coped in (IV) oxide SnO₂:F, with the electrodes deposited thereon. Because of appropriate resistance of the conductive layer of fluorine doped tin (IV) oxide SnO₂:F it becomes a heating layer when connected to a voltage source.

In preferred embodiment the photovoltaic panel is characterized in that the front part is made from glass.

In recommended embodiment the photovoltaic panel is characterized in that the front part is covered with the conductive layer of fluorine doped tin (IV) oxide SnO₂:F on the inside.

Still in another embodiment the photovoltaic panel is characterized in that a layer of transparent polymer film is applied between the conductive layer of fluorine doped tin (IV) oxide SnO₂:F and the photovoltaic cell. Advantageously, the layer of transparent polymer film is an ethylene-vinyl acetate (EVA) film or a polyvinyl butyral (PVB) film.

Yet in another embodiment the photovoltaic panel is characterized in that a layer of transparent polymer film is inseparably bound with the conductive layer of fluorine doped tin (IV) oxide SnO₂:F and/or the photovoltaic cell.

In another recommended embodiment the photovoltaic panel is characterized in that the electrodes are placed on opposite edges, which results in uniform temperature distribution.

The advantage of the invention is a short time required to reach the operating temperature, and uniform temperature distribution on the surface of the photovoltaic panel. Besides, the solution provides for lower heat loss during defrosting, de-icing and the snow removal of the photovoltaic panel.

The solution according to the invention is shown on the drawing, where

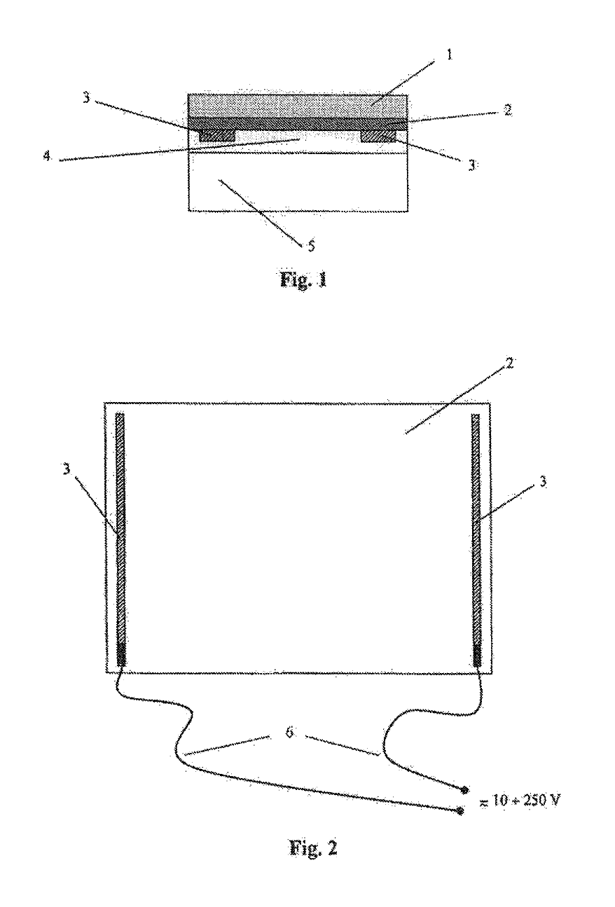

FIG. 1 shows cross-section of the photovoltaic panel, and

FIG. 2 shows a conductive layer of fluorine doped tin (IV) oxide SnO₂:F, and the elements of the heating circuit of the photovoltaic panel.

In shown embodiment the photovoltaic panel consists of the frame (not shown in the figure) and the front part 1 made of flat glass plate. On the front part 1 a thin film of conductive layer 2 of fluorine doped tin (IV) oxide SnO₂:F (FTO) is applied. Coated front part 1 is inseparably and permanently bound to the photovoltaic cell 5, for example in the process of lamination at a temperature ≦200° C. with use of a transparent polymer film 4. This transparent polymer film 4 is form example an ethylene-vinyl acetate (EVA) film or a polyvinyl butyral (PVB) film. As a result of this operation, the conductive layer 2 of fluorine doped in (IV) oxide SnO₂:F which is an electrical heating element, is galvanicly isolated from the photovoltaic cell 5. On the conductive layer 2 of fluorine doped tin (IV) oxide SnO₂:F, the electrodes 3 Made of electrically conductive material are deposited, preferably opposite to each other. The electrodes 3 are connected to the power leads 6.

Operation of the invention is as follows: power leads 6 are connected to the voltage source, DC or AC, for example of the voltage value of 10+250V. As a result of applied voltage electric current flows through the conductive layer 2 of fluorine doped tin (IV) oxide SnO₂:F and produces heat on the resistance of this layer. Produced heat penetrates through the front part 1 towards a layer of frost, ice or snow, which melts exposing the photovoltaic cell 5.

1. Use of fluorine doped tin oxide SnO₂F operative as a heating layer on a photovoltaic panel.

2. A photovoltaic panel comprising:
a front part (1) and a frame comprising at least one photovoltaic cell (5) thereon characterized in that:
the front part (1) is covered with a conductive layer (2) of fluorine doped tin (IV) oxide SnO₂:F, with the electrodes (3) deposited thereon, such that the conductive layer (2) becomes a heating layer when the electrodes (3) are connected to a voltage source.

3. The panel according to claim 2 characterized in that:
the front part (1) is made from glass.

4. The panel according to claim 2 characterized in that:
the front part (1) is covered with the conductive layer (2) of fluorine doped tin (IV) oxide SNO₂:F on the inside.

5. The panel according to claim 4 characterized in that:
a layer of transparent polymer film (4) is applied between the conductive layer (2) of fluorine doped tin (IV) oxide SnO₂:F and the photovoltaic cell (5).

6. The panel according to claim 5 characterized in that:
the layer of transparent polymer film (4) is inseparably bound with the conductive layer (2) of fluorine doped tin (IV) oxide SnO₂:F and/or the photovoltaic cell (5).

7. The panel according to claim 5 characterized in that:
the layer of transparent polymer film (4) is an ethylene-vinyl acetate (EVA) film.

8. The panel according to claim 5 characterized in that:
the layer of transparent polymer film (4) is a polyvinyl butryal (PVB) film.

9. The panel according to claim 2 characterized in that:
the electrodes (3) are placed on opposite edges of the panel.
